(19) United States
(12) Patent Application Publication
(10) Pub. No.: US 2012/0027126 A1
(43) Pub. Date: Feb. 2, 2012

(54) APPARATUS AND METHOD FOR CONSTELLATION REARRANGEMENT IN BROADBAND WIRELESS ACCESS SYSTEM

(75) Inventor: Sung-Eun PARK, Seoul (KR)

(73) Assignee: SAMSUNG ELECTRONICS CO. LTD., Suwon-si (KR)

(21) Appl. No.: 13/194,198

(22) Filed: Jul. 29, 2011

(30) Foreign Application Priority Data
Aug. 2, 2010 (KR) 10-2010-0074698

(51) Int. Cl. H04L 27/36; H03K 9/00; H03D 1/24; H04L 27/00

(52) U.S. Cl. 375/298; 375/295; 375/316; 375/320

(57) ABSTRACT

An apparatus and a method for operating a transmitter supporting constellation rearrangement for 256-Quadrature Amplitude Modulation (QAM) in a broadband wireless access system are provided. The method include generating complex symbols according to a first version of a constellation mapping rule, transmitting an initial transmit packet comprising the complex symbols, and when retransmitting the initial transmit packet, generating complex symbols according to a second first version of a constellation mapping rule.

### PRIORITY

This application claims the benefit under 35 U.S.C. §119(a) of a Korean patent application filed in the Korean Intellectual Property Office on Aug. 2, 2010 and assigned Serial No. 10-2010-0074698, the entire disclosure of which is hereby incorporated by reference.

### BACKGROUND OF THE INVENTION

1. Field of the Invention

The present invention relates to a broadband wireless access system. More particularly, the present invention relates to an apparatus and a method for improving a transfer rate through constellation rearrangement in a broadband wireless access system.

2. Description of the Related Art

In current high rate mobile communications, many wireless communication technologies have been suggested. Among the wireless communication technologies, an Orthogonal Frequency Division Multiplexing (OFDM) technology is acknowledged as the most dominant next-generation wireless communication technology. The OFDM scheme transmits data using a multi-carrier.

To transmit data including a bitstream, modulation, that is, constellation mapping, is conducted. For example, a constellation of 256-Quadrature Amplitude Modulation (QAM) is illustrated in FIG. 1. FIG. 1 illustrates a constellation of the 256-QAM in a broadband wireless access system. Referring to FIG. 1, one point represents 8-bit bitstream, and the 8-bit input bitstream is mapped to one point in the constellation according to its corresponding value.

In high-order modulation over 16-QAM, reliability varies according to the bit mapped in a signal constellation. That is, the bits mapped to one symbol have different reliabilities according to their occupation location. Although the symbol is retransmitted using a Hybrid Automatic Repeat reQuest (HARQ) scheme, it is most likely that the bit of the low reliability is decoded wrong. Hence, a method for overcoming the reliability deviation per bit is demanded.

### SUMMARY OF THE INVENTION

Aspects of the present invention are to address at least the above-mentioned problems and/or disadvantages and to provide at least the advantages described below. Accordingly, an aspect of the present invention is to provide an apparatus and a method for overcoming reliability deviation per bit in a broadband wireless access system.

Another aspect of the present invention is to provide an apparatus and a method for supporting constellation rearrangement for 256-QAM in a broadband wireless access system.

In accordance with an aspect of the present invention, a method of a transmitter in a broadband wireless access system is provided. The method includes generating complex symbols according to a first version of a constellation mapping rule, transmitting an initial transmit packet comprising the complex symbols, and when retransmitting the initial transmit packet, generating complex symbols according to a second first version of a constellation mapping rule.

In accordance with another aspect of the present invention, a method of a receiver in a broadband wireless access system is provided. The method includes verifying a constellation rearrangement version of a received packet, when the version is a first version, restoring a bitstream from complex symbols according to the first version of a constellation mapping rule, and when the version is a second version, restoring a bitstream from complex symbols according to the second version of a constellation mapping rule.

In accordance with yet another aspect of the present invention, an apparatus of a transmitter in a broadband wireless access system is provided. The apparatus includes a constellation mapper for generating complex symbols according to a first version of a constellation mapping rule or a second version, and a controller for controlling to generate complex symbols according to the first version in initial transmission, and to generate complex symbols according to the second version in packet retransmission.

In accordance with still another aspect of the present invention, an apparatus of a receiver in a broadband wireless access system is provided. The apparatus includes a controller for verifying a constellation rearrangement version of a received packet, and a constellation demapper for restoring a bitstream from complex symbols according to a first version of a constellation mapping rule when the version is the first version, and restoring a bitstream from complex symbols according to a second version of a constellation mapping rule when the version is the second version.

Other aspects, advantages, and salient features of the invention will become apparent to those skilled in the art from the following detailed description, which, taken in conjunction with the annexed drawings, discloses exemplary embodiments of the invention.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a constellation of 256-QAM in a wireless access system according to the related art;

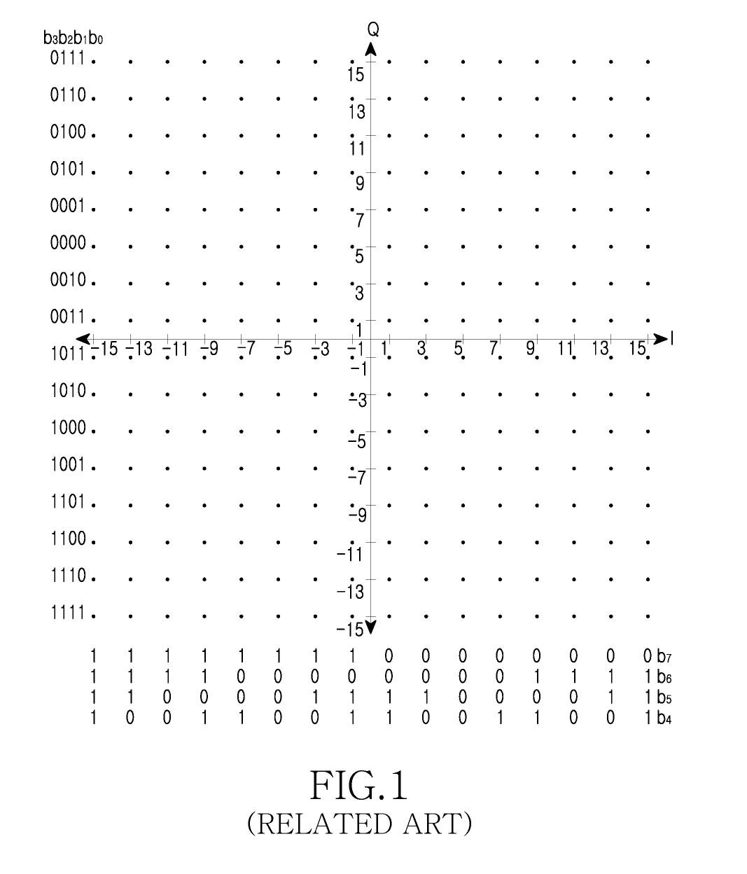

FIG. 2 illustrates reliability per bit for 256-QAM in a broadband wireless access system according to an exemplary embodiment of the present invention;

FIG. 3 illustrates operations of a transmitter in a broadband wireless access system according to an exemplary embodiment of the present invention;

FIG. 4 illustrates operations of a receiver in a broadband wireless access system according to an exemplary embodiment of the present invention;

FIG. 5 illustrates a transmitter in a broadband wireless access system according to an exemplary embodiment of the present invention; and

FIG. 6 illustrates a receiver in a broadband wireless access system according to an exemplary embodiment of the present invention.

Throughout the drawings, like reference numerals will be understood to refer to like parts, components and structures.

### DETAILED DESCRIPTION OF EXEMPLARY EMBODIMENTS

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and words used in the following description and claims are not limited to the bibliographical meanings, but, are merely used by the inventor to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

By the term “substantially” it is meant that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

Exemplary embodiments of the present invention provide a technique for overcoming deviation of reliability per bit in a broadband wireless access system. Hereinafter, an Orthogonal Frequency Division Multiplexing (OFDM)/Orthogonal Frequency Division Multiple Access (OFDMA) wireless communication system is described by way of example. However, the present invention is equally applicable to other wireless access systems.

In high-order modulation over 16-Quadrature Amplitude Modulation (QAM), reliability varies per bit mapped in a signal constellation. Based on this, the bit locations can be rearranged to equalize overall reliability when the bits are combined for the retransmission, which is referred to as Constellation Rearrangement (CoRe). To apply the CoRe scheme to the system of the 256-QAM, the present invention provides a CoRe method for the 256-QAM modulation

Hereinafter, while the 256-QAM modulation is exemplified, the present invention is similarly applicable to the modulation of other various orders.

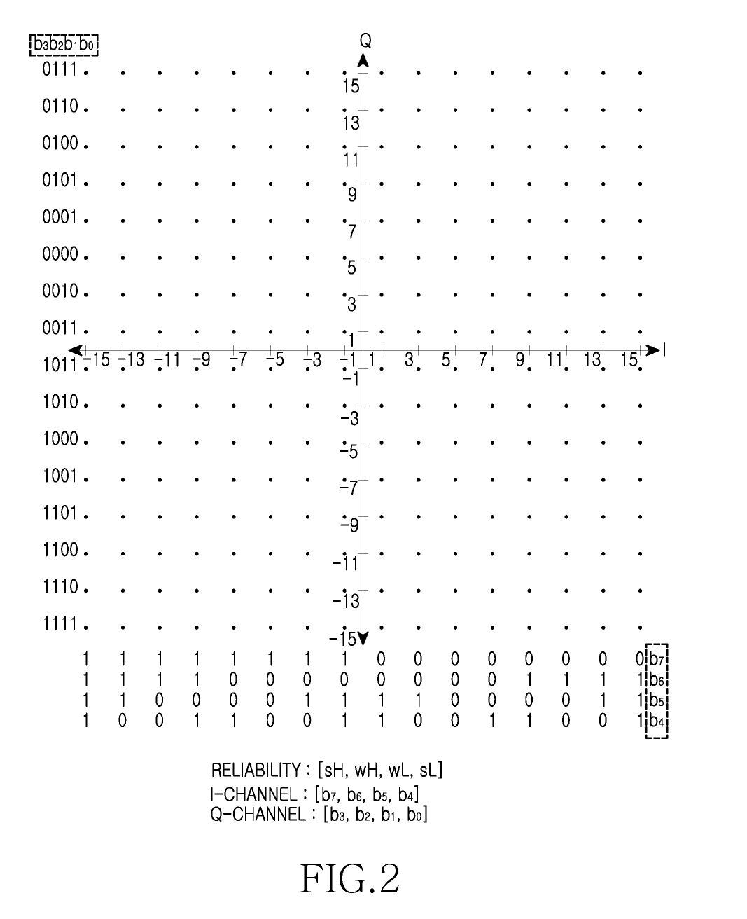

FIG. 2 illustrates reliability per bit for the 256-QAM in a broadband wireless access system according to an exemplary embodiment of the present invention.

Referring to FIG. 2, 8-bit input bitstream [b7, b6, b5, b4, b3, b2, b1, b 0] is mapped to one point in the signal constellation. Of the 8-bit input bitstream, four bits [b7, b6, b5, b4] are mapped to an In-phase (I) channel and the other four bits [b3, b2, b1, b0] are mapped to a Quadrature-phase (Q) channel. The four bits mapped to the I channel and the Q channel respectively have different reliability levels. In an exemplary implementation, for ease of understanding, the reliability level is divided into four levels and are defined as strong High (sH), weak High (wK), weak Low (wL), and strong Low (sL) in a descending order. Accordingly, b7 and b2 are mapped to the highest reliability sH, b6 and b2 are mapped to the second highest reliability wH, b5 and b1 are mapped to the reliability wL lower than wH, and b4 and b0 are mapped to the lowest reliability sL.

In a Hybrid Automatic Repeat reQuest (HARQ) retransmission, the bit mapped to the location of sH in an initial transmission is mapped to the location of sL, the bit mapped to the location of wH in the initial transmission is mapped to the location of wL, the bit mapped to the location of wL in the initial transmission is mapped to the location of wH, and the bit mapped to the location of sL in the initial transmission is mapped to the location of sH. Namely, the bit at the location of the high reliability in the initial transmission is mapped to the location of the low reliability in the retransmission.

More specifically, when a Multiple Input Multiple Output (MIMO) stream is 1, a CoRe mapping rule for the 256-QAM is defined as below. When a Constellation Rearrangement Version (CRV) is changed from 0 to 1, the following rule is applied.

1) sH and sL, and wH and wL are exchanged.

2) The I channel and the Q channel are exchanged.

The CoRe mapping rule for the 256-QAM when the MIMO stream is 1 in conformity with the above rule is shown in Table 1.

TABLE 1

| Constellation | N_{mod} | CRV | Mapping Rule | | | | | | | |
|---|---|---|---|---|---|---|---|---|---|---|
| 256-QAM | 8 | 0 | b0 | b1 | b2 | b3 | b4 | b5 | b6 | b7 |
| 256-QAM | 8 | 1 | b7 | b6 | b5 | b4 | b3 | b2 | b1 | b0 |

In Table 1, N_{mod}, which is a modulation order, denotes a number of input bits mapped to one point in the constellation, and CRV denotes the constellation rearrangement version.

The CRV, which is a 1-bit control signal indicating the constellation rearrangement version, is included to a MAP and delivered together with resource allocation information, to inform a receiver of the constellation mapping rule. Hence, the mapping rule applied to a corresponding subpacket is determined by the value of the CRV. When the initial transmission and the retransmission of the subpacket are performed over persistent allocation resource, the MAP for the retransmission may not be transmitted. At this time, in the downlink transmission, only a starting value of the CRV is transmitted through the initial MAP. In contrast, in the uplink transmission, the value of the CRV is not transmitted but can be implicitly determined between a base station and a terminal in a preset manner.

The change of the CRV, that is, the change of the constellation mapping rule can be fulfilled when all of the bits of the corresponding subpacket are transmitted and the same bits are retransmitted. In other words, the CRV can be changed when the transmitted bits reach the end of a circular buffer of the corresponding subpacket.

Another CoRe mapping rule for the 256-QAM when the MIMO stream is 1 is defined as below. When the CRV is changed from 0 to 1, the following rule is applied.

1) sH and sL, and wH and wL are exchanged.

2) The I channel and the Q channel are not exchanged.

The CoRe mapping rule for the 256-QAM when the MIMO stream is 1 in conformity with the above rule is shown in Table 2.

TABLE 2

| Constellation | N_{mod} | CRV | Mapping Rule | | | | | | | |
|---|---|---|---|---|---|---|---|---|---|---|
| 256-QAM | 8 | 0 | b0 | b1 | b2 | b3 | b4 | b5 | b6 | b7 |
| 256-QAM | 8 | 1 | b3 | b2 | b1 | b0 | b7 | b6 | b5 | b4 |

A CoRe mapping rule for the 256-QAM when the MIMO stream exceeds 1, that is, when the MIMO stream is equal to or greater than 2 is defined as below. When the CRV is changed from 0 to 1, the following rule is applied.

1) sH and sL, and wH and wL are exchanged.

2) The I channel and the Q channel are not exchanged.

3) sH and sL are exchanged within the same symbol.

4) wH and wL are exchanged between two symbols including an even symbol and an odd symbol.

A CoRe mapping rule for the 256-QAM when the MIMO stream is greater than 1 based on the above rule is shown in Table 3.

TABLE 3

| Constellation | N_{mod} | CRV | | | | | | | | |
|---|---|---|---|---|---|---|---|---|---|---|
| | | | Mapping Rule - even symbol | | | | | | | |
| 256-QAM | 8 | 0 | b0 | b1 | b2 | b3 | b4 | b5 | b6 | b7 |
| 256-QAM | 8 | 1 | b3 | b10 | b9 | b0 | b7 | b14 | b13 | b4 |
| | | | Mapping Rule - odd symbol | | | | | | | |
| 256-QAM | 8 | 0 | b8 | b9 | b10 | b11 | b12 | b13 | b14 | b15 |
| 256-QAM | 8 | 1 | b11 | b2 | b1 | b8 | b15 | b6 | b5 | b12 |

In Table 3, when the MIMO stream is greater than 1, two QAM symbol pairs use one CRV value.

Yet another CoRe mapping rule for the 256-QAM when the MIMO stream exceeds 1, that is, when the MIMO stream is equal to or greater than 2 is defined as below. When the CRV is changed from 0 to 1, the following rule is applied.

1) sH and sL, and wH and wL are exchanged.

2) The I channel and the Q channel are not exchanged.

3) sH and sL are exchanged between the even symbol and the odd symbol.

4) wH and wL are exchanged within the same symbol.

A CoRe mapping rule for the 256-QAM when the MIMO stream is greater than 1 based on the above rule is shown in Table 4.

TABLE 4

| Constellation | N_{mod} | CRV | | | | | | | | |
|---|---|---|---|---|---|---|---|---|---|---|
| | | | Mapping Rule - even symbol | | | | | | | |
| 256-QAM | 8 | 0 | b0 | b1 | b2 | b3 | b4 | b5 | b6 | b7 |
| 256-QAM | 8 | 1 | b11 | b2 | b1 | b8 | b15 | b6 | b5 | b12 |
| | | | Mapping Rule - odd symbol | | | | | | | |
| 256-QAM | 8 | 0 | b8 | b9 | b10 | b11 | b12 | b13 | b14 | b15 |
| 256-QAM | 8 | 1 | b3 | b10 | b9 | b0 | b7 | b14 | b13 | b4 |

In Table 4, when the MIMO stream is greater than 1, two QAM symbol pairs use one CRV value.

Still another CoRe mapping rule for the 256-QAM when the MIMO stream exceeds 1, that is, when the MIMO stream is equal to or greater than 2 is defined as below. When the CRV is changed from 0 to 1, the following rule is applied.

1) sH and sL, and wH and wL are exchanged.

2) The I channel and the Q channel are not exchanged.

3) sH and sL are exchanged between the even symbol and the odd symbol.

4) wH and wL are exchanged between the even symbol and the odd symbol.

A CoRe mapping rule for the 256-QAM when the MIMO stream is greater than 1 based on the above rule is shown in Table 5.

TABLE 5

| Constellation | N_{mod} | CRV | | | | | | | | |
|---|---|---|---|---|---|---|---|---|---|---|
| | | | Mapping Rule - even symbol | | | | | | | |
| 256-QAM | 8 | 0 | b0 | b1 | b2 | b3 | b4 | b5 | b6 | b7 |
| 256-QAM | 8 | 1 | b11 | b10 | b9 | b8 | b15 | b14 | b13 | b12 |
| | | | Mapping Rule - odd symbol | | | | | | | |
| 256-QAM | 8 | 0 | b8 | b9 | b10 | b11 | b12 | b13 | b14 | b15 |
| 256-QAM | 8 | 1 | b3 | b2 | b1 | b0 | b7 | b6 | b5 | b4 |

In Table 5, when the MIMO stream is greater than 1, two QAM symbol pairs use one CRV value.

A further CoRe mapping rule for the 256-QAM when the MIMO stream exceeds 1, that is, when the MIMO stream is equal to or greater than 2 is defined as below. When the CRV is changed from 0 to 1, the following rule is applied.

1) sH and sL, and wH and wL are exchanged.

2) The I channel and the Q channel are exchanged.

3) sH and sL are exchanged within the same symbol.

4) wH and wL are exchanged between the even symbol and the odd symbol.

A CoRe mapping rule for the 256-QAM when the MIMO stream is greater than 1 based on the above rule is shown in Table 6.

TABLE 6

| Constellation | N_{mod} | CRV | | | | | | | | |
|---|---|---|---|---|---|---|---|---|---|---|
| | | | Mapping Rule - even symbol | | | | | | | |
| 256-QAM | 8 | 0 | b0 | b1 | b2 | b3 | b4 | b5 | b6 | b7 |
| 256-QAM | 8 | 1 | b7 | b14 | b13 | b4 | b3 | b10 | b9 | b0 |
| | | | Mapping Rule - odd symbol | | | | | | | |
| 256-QAM | 8 | 0 | b8 | b9 | b10 | b11 | b12 | b13 | b14 | b15 |
| 256-QAM | 8 | 1 | b15 | b6 | b5 | b12 | b11 | b2 | b1 | b8 |

In Table 6, when the MIMO stream is greater than 1, two QAM symbol pairs use one CRV value.

A further CoRe mapping rule for the 256-QAM when the MIMO stream exceeds 1, that is, when the MIMO stream is equal to or greater than 2 is defined as below. When the CRV is changed from 0 to 1, the following rule is applied.

1) sH and sL, and wH and wL are exchanged.

2) The I channel and the Q channel are exchanged.

3) sH and sL are exchanged between the even symbol and the odd symbol.

4) wH and wL are exchanged within the same symbol.

A CoRe mapping rule for the 256-QAM when the MIMO stream is greater than 1 based on the above rule is shown in Table 7.

TABLE 7

| Constellation | N_{mod} | CRV | | | | | | | | |
|---|---|---|---|---|---|---|---|---|---|---|
| | | | Mapping Rule - even symbol | | | | | | | |
| 256-QAM | 8 | 0 | b0 | b1 | b2 | b3 | b4 | b5 | b6 | b7 |
| 256-QAM | 8 | 1 | b15 | b6 | b5 | b12 | b11 | b2 | b1 | b8 |
| | | | Mapping Rule - odd symbol | | | | | | | |
| 256-QAM | 8 | 0 | b8 | b9 | b10 | b11 | b12 | b13 | b14 | b15 |
| 256-QAM | 8 | 1 | b7 | b14 | b13 | b4 | b3 | b10 | b9 | b0 |

In Table 7, when the MIMO stream is greater than 1, two QAM symbol pairs use one CRV value.

A further CoRe mapping rule for the 256-QAM when the MIMO stream exceeds 1, that is, when the MIMO stream is equal to or greater than 2 is suggested. When the CRV is changed from 0 to 1, the following rule is applied.

1) sH and sL, and wH and wL are exchanged.

2) The I channel and the Q channel are exchanged.

3) sH and sL are exchanged between the even symbol and the odd symbol.

4) wH and wL are exchanged between the even symbol and the odd symbol.

A CoRe mapping rule for the 256-QAM when the MIMO stream is greater than 1 based on the above rule is shown in Table 8.

TABLE 8

| Constellation | N_{mod} | CRV | | | | | | | | |
|---|---|---|---|---|---|---|---|---|---|---|
| | | | Mapping Rule - even symbol | | | | | | | |
| 256-QAM | 8 | 0 | b0 | b1 | b2 | b3 | b4 | b5 | b6 | b7 |
| 256-QAM | 8 | 1 | b15 | b14 | b13 | b12 | b11 | b10 | b9 | b8 |
| | | | Mapping Rule - odd symbol | | | | | | | |
| 256-QAM | 8 | 0 | b8 | b9 | b10 | b11 | b12 | b13 | b14 | b15 |
| 256-QAM | 8 | 1 | b7 | b6 | b5 | b4 | b3 | b2 | b1 | b0 |

In Table 8, when the MIMO stream is greater than 1, two QAM symbol pairs use one CRV value.

According to the CoRe rule for Table 1 through Table 8, the system according to an exemplary embodiment of the present invention rearranges the bits to equalize overall reliability when the bits are combined through the HARQ retransmission in the 256-QAM.

Now, operations and structures of a transmitter and a receiver for communicating while changing the above correlation mapping rule are described in more detail below.

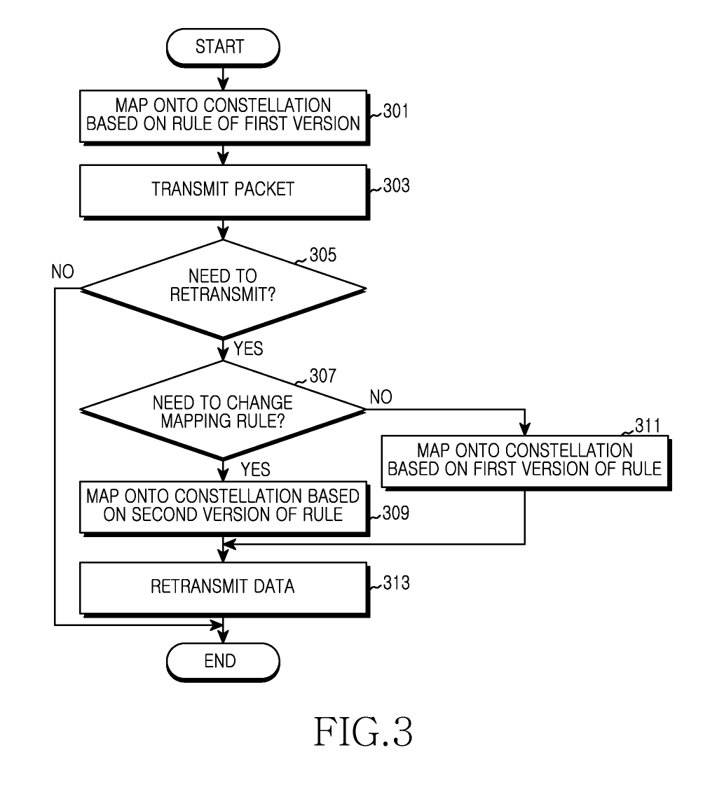

FIG. 3 illustrates operations of a transmitter in a broadband wireless access system according to an exemplary embodiment of the present invention.

Referring to FIG. 3, the transmitter performs a constellation mapping of a transmit bitstream according a first version of a constellation mapping rule in step 301. For example, the first version of the constellation mapping rule can be the mapping rule corresponding to the CRV 0 of Table 1 through Table 8. More specifically, the transmitter divides the transmit bitstream into bits per symbol according to a modulation scheme, determines a location of each bit according to the first version of the constellation mapping rule, and then generates complex symbols through the constellation mapping. Herein, the modulation scheme can employ the 256-QAM, and the bits per symbol can be 8 bits.

In step 303, the transmitter transmits a packet. That is, after the constellation mapping, the transmitter generates OFDM symbols from the complex symbols using an Inverse Fast Fourier Transform (IFFT) operation and a Cyclic Prefix (CP) insertion, up-converts the OFDM symbols to a Radio Frequency (RF) signal, and then transmits the RF signal over an antenna.

In step 305, the transmitter determines whether retransmission of the packet is necessary. The transmitter can determine whether the retransmission is necessary, by verifying a control signaling indicating reception success or failure of the packet from the receiver. That is, when receiving an ACKnowledgement (ACK) from the receiver, the transmitter determines that the retransmission is not necessary and ends the process. In contrast, when receiving a Non-ACK (HACK), the transmitter determines that the retransmission is necessary.

Upon determining that the retransmission is necessary, the transmitter determines whether it is necessary to change the constellation mapping rule in step 307. Whether it is necessary to change the constellation mapping rule can be determined variously according to exemplary embodiments of the present invention. For example, the constellation mapping rule can be changed when the retransmission is conducted. Alternatively, the constellation mapping rule can be changed when all of the bits of the corresponding packet are transmitted.

When it is necessary to change the constellation mapping rule, the transmitter maps the transmit bitstream to the constellation according to a second version of the constellation mapping rule in step 309. For example, the second version of the constellation mapping rule can be the mapping rule corresponding to the CRV 1 of Table 1 through Table 8. The constellation mapping rule before the change and the constellation mapping rule after the change shift the bit of the relatively high reliability to the location of the low reliability. More specifically, when a MIMO stream is 1, the relation of the constellation mapping rule before the change and the constellation mapping rule after the change includes at least one feature of a sH-sL exchange, a wH-wL exchange, and an I channel-Q channel exchange. When the MIMO stream is greater than 2, the relation of the constellation mapping rule before the change and the constellation mapping rule after the change includes at least one feature of the sH-sL exchange, the wH-wL exchange, and the I channel-Q channel exchange, and concurrently at least one of the sH-sL exchange and the wH-wL exchange is conducted within the same symbol or between an even symbol and an odd symbol. In contrast, when the change of the constellation mapping rule is unnecessary, the transmitter maps the transmit bitstream to the constellation according to the first version of the constellation mapping rule in step 311.

In step 313, the transmitter transmits the packet. That is, the transmitter conducts the constellation mapping, generates OFDM symbols from the complex symbols using the IFFT operation and the CP insertion, up-converts the OFDM symbols to the RF signal, and then transmits the RF signal via the antenna.

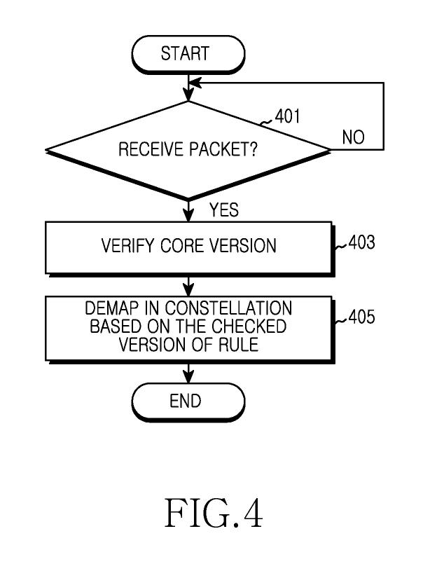

FIG. 4 illustrates operations of a receiver in a broadband wireless access system according to an exemplary embodiment of the present invention.

Referring to FIG. 4, the receiver determines whether a packet is received from a transmitter in step 401. For example, when the receiver is a terminal, the terminal receives the packet over a downlink resource allocated from a base station. When the receiver is a base station, the base station receives the packet over the uplink resource allocated to the terminal.

Upon receiving the packet, the receiver verifies a CoRe version applied to the packet in step 403. For example, when the packet is an initial transmission packet, the CoRe version can be obtained from CRV information of a MAP for allocating the downlink resource for the packet, or implicitly determined in a preset fashion. When the packet is a retransmission packet, the CoRe version can be obtained by determining whether the CoRe version of the initial transmission packet is changed.

In step 405, the receiver performs constellation demapping according to the obtained version of the constellation mapping rule. For example, the constellation mapping rule can be the mapping rule corresponding to CRV 0 or CRV 1 in Table 1 through Table 8. Herein, the constellation mapping rules of the different versions shift the bit of the relatively high reliability to the location of the low reliability. More specifically, when the MIMO stream is 1, the relation of the constellation mapping rules of the different versions includes at least one feature of a sH-sL exchange, a wH-wL exchange, and an I channel-Q channel exchange. When the MIMO stream is greater than 2, the relation of the constellation mapping rule before the change and the constellation mapping rule after the change includes at least one feature of the sH-sL exchange, the wH-wL exchange, and the I channel-Q channel exchange, and concurrently at least one of the sH-sL exchange and the wH-wL exchange is performed within the same symbol or between an even symbol and an odd symbol. That is, the receiver down-converts an RF signal to a baseband signal, restores complex symbols using an FFT operation, and restores a bitstream from the complex symbols through the constellation demapping. In so doing, when the packet is a retransmission packet, the receiver combines the initial transmission packet and the retransmission packet.

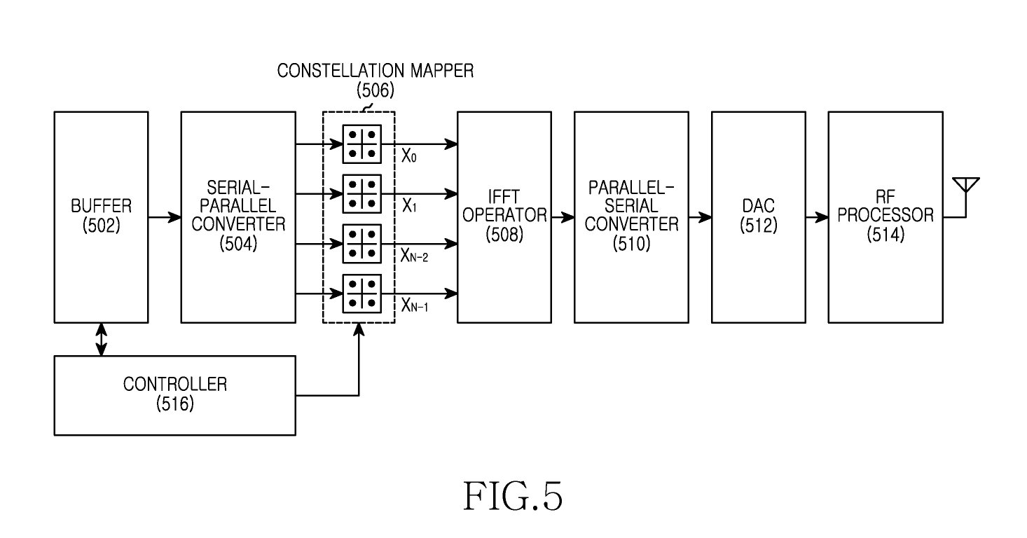

FIG. 5 is a block diagram of a transmitter in a broadband wireless access system according to an exemplary embodiment of the present invention.

Referring to FIG. 5, the transmitter includes a buffer 502, a serial-parallel converter 504, a constellation mapper 506, an IFFT operator 508, a parallel-serial converter 510, a Digital to Analog Converter (DAC) 512, an RF processor 514, and a controller 516.

The buffer 502 temporarily stores transmit data, and outputs the stored data to the serial-parallel converter 504 under control of the controller 516. The serial-parallel converter 504 parallels a transmit bitstream output from the buffer 502 and divides the bitstream into bits per symbol according to a modulation scheme of the constellation mapper 506. Herein, the modulation scheme can be 256-QAM, and the bits per symbol can be 8 bits. The constellation mapper 506 generates complex symbols by mapping the transmit bits output from the serial-parallel converter 504 to the constellation. In so doing, the constellation mapper 506 conducts the constellation mapping according to a constellation mapping rule directed by the controller 516.

The IFFT operator 508 performs the IFFT with the complex symbols output from the constellation mapper 506. The parallel-serial converter 510 converts the result of the IFFT operation to a serial signal and generates the OFDM symbol by inserting a CP. The DAC 512 converts the OFDM symbol to an analog signal. The RF processor 514 up-converts an analog OFDM symbol to an RF signal and transmits the RF signal over an antenna.

The controller 516 controls the output of the buffer 502 and directs the constellation mapping rule to the constellation mapper 506. That is, to reduce reliability deviation according to the location of the bit in the constellation, the controller 516 changes the constellation mapping rule based on a certain condition. For example, the constellation mapping rule can be changed as shown in Table 1 through Table 8. Whether to change the constellation mapping rule can be determined variously according to exemplary embodiments of the present invention. For example, the constellation mapping rule can be changed when retransmission is conducted. Alternatively, the constellation mapping rule can be changed when all of the bits of a corresponding packet are transmitted. Herein, the constellation mapping rules of different versions shift the bit of the relatively high reliability to a location of the low reliability. More specifically, when the MIMO stream is 1, the relation of the constellation mapping rules of the different versions includes at least one feature of the sH-sL exchange, the wH-wL exchange, and the I channel-Q channel exchange. When the MIMO stream is greater than 2, the relation of the constellation mapping rule before the change and the constellation mapping rule after the change includes at least one feature of a sH-sL exchange, a wH-wL exchange, and an I channel-Q channel exchange, and concurrently at least one of the sH-sL exchange and the wH-wL exchange is performed within the same symbol or between an even symbol and an odd symbol.

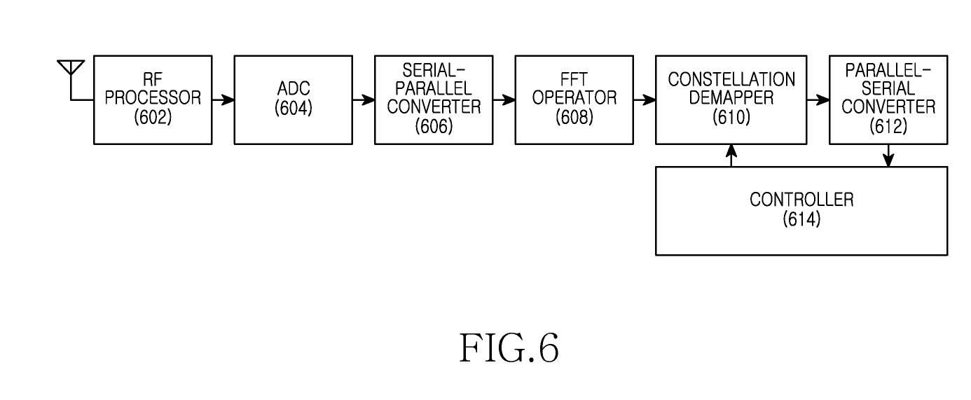

FIG. 6 is a block diagram of a receiver in a broadband wireless access system according to an exemplary embodiment of the present invention.

Referring to FIG. 6, the receiver includes an RF processor 602, an Analog to Digital Converter (ADC) 604, a serial-parallel converter 606, a Fast Fourier Transform (FFT) operator 608, a constellation demapper 610, a parallel-serial converter 612, and a controller 614.

The RF processor 602 down-converts an RF signal received via an antenna to a baseband signal, and the ADC 604 samples and converts the baseband signal to a digital signal. The serial-parallel converter 606 parallels the digital signal. The FFT operator 608 restores complex symbols through the FFT operation with the parallelized signal. The constellation demapper 610 converts the complex symbols to a bitstream using constellation demapping. The constellation demapper 610 conducts the constellation demapping according to a constellation mapping rule directed by the controller 614. The parallel-serial converter 612 serializes the bitstream output from the constellation demapper 610.

The controller 614 directs a constellation mapping rule to the constellation demapper 610. More specifically, the controller 614 determines a CoRe version applied to the packet when the packet is received, and informs the constellation demapper 610 of the constellation mapping rule of the determined version. For example, when the packet is an initial transmission packet, the CoRe version can be obtained from CRV information of a MAP for allocating a downlink resource for the packet, or implicitly determined in a preset fashion. When the packet is a retransmission packet, the CoRe version can be obtained by determining whether the CoRe version of the initial transmission packet is changed. For example, the constellation mapping rule can be the mapping rule corresponding to CRV 0 or CRV in Table 1 through Table 8. Herein, the constellation mapping rules of the different versions shift the bit of the relatively high reliability to the location of the low reliability. More specifically, when the MIMO stream is 1, the relation of the constellation mapping rules of the different versions includes at least one feature of a sH-sL exchange, a wH-wL exchange, and an I channel-Q channel exchange. When the MIMO stream is greater than 2, the relation of the constellation mapping rule before the change and the constellation mapping rule after the change includes at least one feature of the sH-sL exchange, the wH-wL exchange, and the I channel-Q channel exchange, and concurrently at least one of the sH-sL exchange and the wH-wL exchange is performed within the same symbol or between an even symbol and an odd symbol.

As set forth above, the constellation rearrangement for the 256-QAM is supported in a broadband wireless access system, and thus a peak throughput and a link performance can be enhanced when data burst is transmitted.

While the invention has been shown and described with reference to certain exemplary embodiments thereof, it will be understood by those skilled in the art that various changes in form and details may be made therein without departing from the spirit and scope of the invention as defined by the appended claims and their equivalents.

What is claimed is:

1. A method for an operation of a transmitter in a wireless access system, the method comprising:
generating complex symbols according to a first version of a constellation mapping rule;
transmitting an initial transmit packet comprising the complex symbols; and
when retransmitting the initial transmit packet, generating complex symbols according to a second first version of a constellation mapping rule.

2. The method of claim 1, wherein the generating of the complex symbols comprises:
modulating a bitstream according to 256-Quadrature Amplitude Modulation (QAM).

3. The method of claim 2, wherein the first version of the constellation mapping rule and the second version of the constellation mapping rule comprises a relation of at least one of exchange of a first bit and a fourth bit, exchange of a second bit and a third bit, exchange of a fifth bit and an eighth bit, exchange of a sixth bit and a seventh bit, and exchange of an In-phase (I) channel and a Quadrature-phase (Q) channel.

4. The method of claim 3, wherein the first version of the constellation mapping rule is a mapping rule corresponding to a Constellation Rearrangement Version (CRV) 0 in the following table, and
the second version of the constellation mapping rule is a mapping rule corresponding to a CRV 1 in the following table:

| Constellation | N_{mod} | CRV | Mapping Rule | | | | | | | |
|---|---|---|---|---|---|---|---|---|---|---|
| 256-QAM | 8 | 0 | b0 | b1 | b2 | b3 | b4 | b5 | b6 | b7 |
| 256-QAM | 8 | 1 | b7 | b6 | b5 | b4 | b3 | b2 | b1 | b0 |

where N_{mod}, which is a modulation order, denotes a number of input bits mapped to one point in a constellation, and CRV denotes the constellation rearrangement version.

5. The method of claim 3, wherein the first version of the constellation mapping rule is a mapping rule corresponding to a Constellation Rearrangement Version (CRV) 0 in the following table, and
the second version of the constellation mapping rule is a mapping rule corresponding to a CRV 1 in the following table:

| Constellation | N_{mod} | CRV | Mapping Rule | | | | | | | |
|---|---|---|---|---|---|---|---|---|---|---|
| 256-QAM | 8 | 0 | b0 | b1 | b2 | b3 | b4 | b5 | b6 | b7 |
| 256-QAM | 8 | 1 | b3 | b2 | b1 | b0 | b7 | b6 | b5 | b4 |

where N_{mod}, which is a modulation order, denotes a number of input bits mapped to one point in the constellation, and CRV denotes the constellation rearrangement version.

6. The method of claim 3, wherein at least one of the exchange of the first bit and the fourth bit, the exchange of the second bit and the third bit, the exchange of the fifth bit and the eighth bit, and the exchange of the sixth bit and the seventh bit is conducted between an even symbol and an odd symbol.

7. The method of claim 6, wherein the first version of the constellation mapping rule is a mapping rule corresponding to a Constellation Rearrangement Version (CRV) 0 in the following table, and
the second version of the constellation mapping rule is a mapping rule corresponding to a CRV 1 in the following table:

| Constellation | N_{mod} | CRV | | | | | | | | |
|---|---|---|---|---|---|---|---|---|---|---|
| | | | Mapping Rule - even symbol | | | | | | | |
| 256-QAM | 8 | 0 | b0 | b1 | b2 | b3 | b4 | b5 | b6 | b7 |
| 256-QAM | 8 | 1 | b3 | b10 | b9 | b0 | b7 | b14 | b13 | b4 |
| | | | Mapping Rule - odd symbol | | | | | | | |
| 256-QAM | 8 | 0 | b8 | b9 | b10 | b11 | b12 | b13 | b14 | b15 |
| 256-QAM | 8 | 1 | b11 | b2 | b1 | b8 | b15 | b6 | b5 | b12 |

where N_{mod}, which is a modulation order, denotes a number of input bits mapped to one point in the constellation, and CRV denotes the constellation rearrangement version.

8. The method of claim 6, wherein the first version of the constellation mapping rule is a mapping rule corresponding to a Constellation Rearrangement Version (CRV) 0 in the following table, and
the second version of the constellation mapping rule is a mapping rule corresponding to a CRV 1 in the following table:

| Constellation | N_{mod} | CRV | | | | | | | | |
|---|---|---|---|---|---|---|---|---|---|---|
| | | | Mapping Rule - even symbol | | | | | | | |
| 256-QAM | 8 | 0 | b0 | b1 | b2 | b3 | b4 | b5 | b6 | b7 |
| 256-QAM | 8 | 1 | b11 | b2 | b1 | b8 | b15 | b6 | b5 | b12 |
| | | | Mapping Rule - odd symbol | | | | | | | |
| 256-QAM | 8 | 0 | b8 | b9 | b10 | b11 | b12 | b13 | b14 | b15 |
| 256-QAM | 8 | 1 | b3 | b10 | b9 | b0 | b7 | b14 | b13 | b4 |

where N_{mod}, which is a modulation order, denotes a number of input bits mapped to one point in the constellation, and CRV denotes the constellation rearrangement version.

9. The method of claim 6, wherein the first version of the constellation mapping rule is a mapping rule corresponding to a Constellation Rearrangement Version (CRV) 0 in the following table, and
the second version of the constellation mapping rule is a mapping rule corresponding to a CRV 1 in the following table:

| Constellation | N_{mod} | CRV | | | | | | | | |
|---|---|---|---|---|---|---|---|---|---|---|
| | | | Mapping Rule - even symbol | | | | | | | |
| 256-QAM | 8 | 0 | b0 | b1 | b2 | b3 | b4 | b5 | b6 | b7 |
| 256-QAM | 8 | 1 | b11 | b10 | b9 | b8 | b15 | b14 | b13 | b12 |
| | | | Mapping Rule - odd symbol | | | | | | | |
| 256-QAM | 8 | 0 | b8 | b9 | b10 | b11 | b12 | b13 | b14 | b15 |
| 256-QAM | 8 | 1 | b3 | b2 | b1 | b0 | b7 | b6 | b5 | b4 |

where N_{mod}, which is a modulation order, denotes a number of input bits mapped to one point in the constellation, and CRV denotes the constellation rearrangement version.

10. The method of claim 6, wherein the first version of the constellation mapping rule is a mapping rule corresponding to a Constellation Rearrangement Version (CRV) 0 in the following table, and
the second version of the constellation mapping rule is a mapping rule corresponding to a CRV 1 in the following table:

| Constellation | N_{mod} | CRV | | | | | | | | |
|---|---|---|---|---|---|---|---|---|---|---|
| | | | Mapping Rule - even symbol | | | | | | | |
| 256-QAM | 8 | 0 | b0 | b1 | b2 | b3 | b4 | b5 | b6 | b7 |
| 256-QAM | 8 | 1 | b7 | b14 | b13 | b4 | b3 | b10 | b9 | b0 |
| | | | Mapping Rule - odd symbol | | | | | | | |
| 256-QAM | 8 | 0 | b8 | b9 | b10 | b11 | b12 | b13 | b14 | b15 |
| 256-QAM | 8 | 1 | b15 | b6 | b5 | b12 | b11 | b2 | b1 | b8 |

where N_{mod}, which is a modulation order, denotes a number of input bits mapped to one point in the constellation, and CRV denotes the constellation rearrangement version.

11. The method of claim 6, wherein the first version of the constellation mapping rule is a mapping rule corresponding to a Constellation Rearrangement Version (CRV) 0 in the following table, and
the second version of the constellation mapping rule is a mapping rule corresponding to a CRV 1 in the following table:

| Constellation | N_{mod} | CRV | | | | | | | | |
|---|---|---|---|---|---|---|---|---|---|---|
| | | | Mapping Rule - even symbol | | | | | | | |
| 256-QAM | 8 | 0 | b0 | b1 | b2 | b3 | b4 | b5 | b6 | b7 |
| 256-QAM | 8 | 1 | b15 | b6 | b5 | b12 | b11 | b2 | b1 | b8 |
| | | | Mapping Rule - odd symbol | | | | | | | |
| 256-QAM | 8 | 0 | b8 | b9 | b10 | b11 | b12 | b13 | b14 | b15 |
| 256-QAM | 8 | 1 | b7 | b14 | b13 | b4 | b3 | b10 | b9 | b0 |

where N_{mod}, which is a modulation order, denotes a number of input bits mapped to one point in the constellation, and CRV denotes the constellation rearrangement version.

12. The method of claim 6, wherein the first version of the constellation mapping rule is a mapping rule corresponding to a Constellation Rearrangement Version (CRV) 0 in the following table, and
the second version of the constellation mapping rule is a mapping rule corresponding to a CRV 1 in the following table:

| Constellation | N_{mod} | CRV | | | | | | | | |
|---|---|---|---|---|---|---|---|---|---|---|
| | | | Mapping Rule - even symbol | | | | | | | |
| 256-QAM | 8 | 0 | b0 | b1 | b2 | b3 | b4 | b5 | b6 | b7 |
| 256-QAM | 8 | 1 | b15 | b14 | b13 | b12 | b11 | b10 | b9 | b8 |
| | | | Mapping Rule - odd symbol | | | | | | | |
| 256-QAM | 8 | 0 | b8 | b9 | b10 | b11 | b12 | b13 | b14 | b15 |
| 256-QAM | 8 | 1 | b7 | b6 | b5 | b4 | b3 | b2 | b1 | b0 |

where N_{mod}, which is a modulation order, denotes a number of input bits mapped to one point in the constellation, and CRV denotes the constellation rearrangement version.

13. A method for an operation of a receiver in a wireless access system, comprising:
verifying a constellation rearrangement version of a received packet;
when the version is a first version, restoring a bitstream from complex symbols according to the first version of a constellation mapping rule; and
when the version is a second version, restoring a bitstream from complex symbols according to the second version of a constellation mapping rule.

14. The method of claim 13, wherein the restoring of the bitstream comprises:
demodulating the complex symbols according to 256-Quadrature Amplitude Modulation (QAM).

15. The method of claim 14, wherein the first version of the constellation mapping rule and the second version of the constellation mapping rule comprises a relation of at least one of exchange of a first bit and a fourth bit, exchange of a second bit and a third bit, exchange of a fifth bit and an eighth bit, exchange of a sixth bit and a seventh bit, and exchange of an In-phase (I) channel and a Quadrature-phase (Q) channel.

16. The method of claim 15, wherein the first version of the constellation mapping rule is a mapping rule corresponding to a Constellation Rearrangement Version (CRV) 0 in the following table, and
the second version of the constellation mapping rule is a mapping rule corresponding to a CRV 1 in the following table:

| Constellation | N_{mod} | CRV | Mapping Rule | | | | | | | |
|---|---|---|---|---|---|---|---|---|---|---|
| 256-QAM | 8 | 0 | b0 | b1 | b2 | b3 | b4 | b5 | b6 | b7 |
| 256-QAM | 8 | 1 | b7 | b6 | b5 | b4 | b3 | b2 | b1 | b0 |

where N_{mod}, which is a modulation order, denotes a number of input bits mapped to one point in a constellation, and CRV denotes the constellation rearrangement version.

17. The method of claim 15, wherein the first version of the constellation mapping rule is a mapping rule corresponding to a Constellation Rearrangement Version (CRV) 0 in the following table, and
the second version of the constellation mapping rule is a mapping rule corresponding to a CRV 1 in the following table:

| Constellation | N_{mod} | CRV | Mapping Rule | | | | | | | |
|---|---|---|---|---|---|---|---|---|---|---|
| 256-QAM | 8 | 0 | b0 | b1 | b2 | b3 | b4 | b5 | b6 | b7 |
| 256-QAM | 8 | 1 | b3 | b2 | b1 | b0 | b7 | b6 | b5 | b4 |

where N_{mod}, which is a modulation order, denotes a number of input bits mapped to one point in the constellation, and CRV denotes the constellation rearrangement version.

18. The method of claim 15, wherein at least one of the exchange of the first bit and the fourth bit, the exchange of the second bit and the third bit, the exchange of the fifth bit and the eighth bit, and the exchange of the sixth bit and the seventh bit is conducted between an even symbol and an odd symbol.

19. The method of claim 18, wherein the first version of the constellation mapping rule is a mapping rule corresponding to a Constellation Rearrangement Version (CRV) 0 in the following table, and
the second version of the constellation mapping rule is a mapping rule corresponding to a CRV 1 in the following table:

| Constellation | N_{mod} | CRV | | | | | | | | |
|---|---|---|---|---|---|---|---|---|---|---|
| | | | Mapping Rule - even symbol | | | | | | | |
| 256-QAM | 8 | 0 | b0 | b1 | b2 | b3 | b4 | b5 | b6 | b7 |
| 256-QAM | 8 | 1 | b3 | b10 | b9 | b0 | b7 | b14 | b13 | b4 |
| | | | Mapping Rule - odd symbol | | | | | | | |
| 256-QAM | 8 | 0 | b8 | b9 | b10 | b11 | b12 | b13 | b14 | b15 |
| 256-QAM | 8 | 1 | b11 | b2 | b1 | b8 | b15 | b6 | b5 | b12 |

where N_{mod}, which is a modulation order, denotes a number of input bits mapped to one point in the constellation, and CRV denotes the constellation rearrangement version.

20. The method of claim 18, wherein the first version of the constellation mapping rule is a mapping rule corresponding to a Constellation Rearrangement Version (CRV) 0 in the following table, and
the second version of the constellation mapping rule is a mapping rule corresponding to a CRV 1 in the following table:

| Constellation | N_{mod} | CRV | | | | | | | | |
|---|---|---|---|---|---|---|---|---|---|---|
| | | | Mapping Rule - even symbol | | | | | | | |
| 256-QAM | 8 | 0 | b0 | b1 | b2 | b3 | b4 | b5 | b6 | b7 |
| 256-QAM | 8 | 1 | b11 | b2 | b1 | b8 | b15 | b6 | b5 | b12 |
| | | | Mapping Rule - odd symbol | | | | | | | |
| 256-QAM | 8 | 0 | b8 | b9 | b10 | b11 | b12 | b13 | b14 | b15 |
| 256-QAM | 8 | 1 | b3 | b10 | b9 | b0 | b7 | b14 | b13 | b4 |

where N_{mod}, which is a modulation order, denotes a number of input bits mapped to one point in the constellation, and CRV denotes the constellation rearrangement version.

21. The method of claim 18, wherein the first version of the constellation mapping rule is a mapping rule corresponding to a Constellation Rearrangement Version (CRV) 0 in the following table, and
the second version of the constellation mapping rule is a mapping rule corresponding to a CRV 1 in the following table:

| Constellation | N_{mod} | CRV | | | | | | | | |
|---|---|---|---|---|---|---|---|---|---|---|
| | | | Mapping Rule - even symbol | | | | | | | |
| 256-QAM | 8 | 0 | b0 | b1 | b2 | b3 | b4 | b5 | b6 | b7 |
| 256-QAM | 8 | 1 | b11 | b10 | b9 | b8 | b15 | b14 | b13 | b12 |
| | | | Mapping Rule - odd symbol | | | | | | | |
| 256-QAM | 8 | 0 | b8 | b9 | b10 | b11 | b12 | b13 | b14 | b15 |
| 256-QAM | 8 | 1 | b3 | b2 | b1 | b0 | b7 | b6 | b5 | b4 |

where N_{mod}, which is a modulation order, denotes a number of input bits mapped to one point in the constellation, and CRV denotes the constellation rearrangement version.

22. The method of claim 18, wherein the first version of the constellation mapping rule is a mapping rule corresponding to a Constellation Rearrangement Version (CRV) 0 in the following table, and
the second version of the constellation mapping rule is a mapping rule corresponding to a CRV 1 in the following table:

| Constellation | N_{mod} | CRV | | | | | | | | |
|---|---|---|---|---|---|---|---|---|---|---|
| | | | Mapping Rule - even symbol | | | | | | | |
| 256-QAM | 8 | 0 | b0 | b1 | b2 | b3 | b4 | b5 | b6 | b7 |
| 256-QAM | 8 | 1 | b7 | b14 | b13 | b4 | b3 | b10 | b9 | b0 |
| | | | Mapping Rule - odd symbol | | | | | | | |
| 256-QAM | 8 | 0 | b8 | b9 | b10 | b11 | b12 | b13 | b14 | b15 |
| 256-QAM | 8 | 1 | b15 | b6 | b5 | b12 | b11 | b2 | b1 | b8 |

where N_{mod}, which is a modulation order, denotes a number of input bits mapped to one point in the constellation, and CRV denotes the constellation rearrangement version.

23. The method of claim 18, wherein the first version of the constellation mapping rule is a mapping rule corresponding to a Constellation Rearrangement Version (CRV) 0 in the following table, and
the second version of the constellation mapping rule is a mapping rule corresponding to a CRV 1 in the following table:

| Constellation | N_{mod} | CRV | | | | | | | | |
|---|---|---|---|---|---|---|---|---|---|---|
| | | | Mapping Rule - even symbol | | | | | | | |
| 256-QAM | 8 | 0 | b0 | b1 | b2 | b3 | b4 | b5 | b6 | b7 |
| 256-QAM | 8 | 1 | b15 | b6 | b5 | b12 | b11 | b2 | b1 | b8 |
| | | | Mapping Rule - odd symbol | | | | | | | |
| 256-QAM | 8 | 0 | b8 | b9 | b10 | b11 | b12 | b13 | b14 | b15 |
| 256-QAM | 8 | 1 | b7 | b14 | b13 | b4 | b3 | b10 | b9 | b0 |

where N_{mod}, which is a modulation order, denotes a number of input bits mapped to one point in the constellation, and CRV denotes the constellation rearrangement version.

24. The method of claim 18, wherein the first version of the constellation mapping rule is a mapping rule corresponding to a Constellation Rearrangement Version (CRV) 0 in the following table, and
the second version of the constellation mapping rule is a mapping rule corresponding to a CRV 1 in the following table:

| Constellation | N_{mod} | CRV | | | | | | | | |
|---|---|---|---|---|---|---|---|---|---|---|
| | | | Mapping Rule - even symbol | | | | | | | |
| 256-QAM | 8 | 0 | b0 | b1 | b2 | b3 | b4 | b5 | b6 | b7 |
| 256-QAM | 8 | 1 | b15 | b14 | b13 | b12 | b11 | b10 | b9 | b8 |
| | | | Mapping Rule - odd symbol | | | | | | | |
| 256-QAM | 8 | 0 | b8 | b9 | b10 | b11 | b12 | b13 | b14 | b15 |
| 256-QAM | 8 | 1 | b7 | b6 | b5 | b4 | b3 | b2 | b1 | b0 |

where N_{mod}, which is a modulation order, denotes a number of input bits mapped to one point in the constellation, and CRV denotes the constellation rearrangement version.

25. An apparatus of a transmitter in a wireless access system, comprising:
a constellation mapper for generating complex symbols according to a first version of a constellation mapping rule or a second version; and
a controller for controlling to generate complex symbols according to the first version in initial transmission, and to generate complex symbols according to the second version in packet retransmission.

26. The apparatus of claim 25, wherein the constellation mapper modulates a bitstream according to 256-Quadrature Amplitude Modulation (QAM).

27. The apparatus of claim 26, wherein the first version of the constellation mapping rule and the second version of the constellation mapping rule comprises a relation of at least one of exchange of a first bit and a fourth bit, exchange of a second bit and a third bit, exchange of a fifth bit and an eighth bit, exchange of a sixth bit and a seventh bit, and exchange of an In-phase (I) channel and a Quadrature-phase (Q) channel.

28. The apparatus of claim 27, wherein the first version of the constellation mapping rule is a mapping rule corresponding to a Constellation Rearrangement Version (CRV) 0 in the following table, and
the second version of the constellation mapping rule is a mapping rule corresponding to a CRV 1 in the following table:

| Constellation | N_{mod} | CRV | Mapping Rule | | | | | | | |
|---|---|---|---|---|---|---|---|---|---|---|
| 256-QAM | 8 | 0 | b0 | b1 | b2 | b3 | b4 | b5 | b6 | b7 |
| 256-QAM | 8 | 1 | b7 | b6 | b5 | b4 | b3 | b2 | b1 | b0 |

where N_{mod}, which is a modulation order, denotes a number of input bits mapped to one point in a constellation, and CRV denotes the constellation rearrangement version.

29. The apparatus of claim 27, wherein the first version of the constellation mapping rule is a mapping rule corresponding to a Constellation Rearrangement Version (CRV) 0 in the following table, and
the second version of the constellation mapping rule is a mapping rule corresponding to a CRV 1 in the following table:

| Constellation | N_{mod} | CRV | Mapping Rule | | | | | | | |
|---|---|---|---|---|---|---|---|---|---|---|
| 256-QAM | 8 | 0 | b0 | b1 | b2 | b3 | b4 | b5 | b6 | b7 |
| 256-QAM | 8 | 1 | b3 | b2 | b1 | b0 | b7 | b6 | b5 | b4 |

where N_{mod}, which is a modulation order, denotes a number of input bits mapped to one point in the constellation, and CRV denotes the constellation rearrangement version.

30. The apparatus of claim 27, wherein at least one of the exchange of the first bit and the fourth bit, the exchange of the second bit and the third bit, the exchange of the fifth bit and the eighth bit, and the exchange of the sixth bit and the seventh bit is conducted between an even symbol and an odd symbol.

31. The apparatus of claim 30, wherein the first version of the constellation mapping rule is a mapping rule corresponding to a Constellation Rearrangement Version (CRV) 0 in the following table, and
the second version of the constellation mapping rule is a mapping rule corresponding to a CRV 1 in the following table:

| Constellation | N_{mod} | CRV | | | | | | | | |
|---|---|---|---|---|---|---|---|---|---|---|
| | | | Mapping Rule - even symbol | | | | | | | |
| 256-QAM | 8 | 0 | b0 | b1 | b2 | b3 | b4 | b5 | b6 | b7 |
| 256-QAM | 8 | 1 | b3 | b10 | b9 | b0 | b7 | b14 | b13 | b4 |
| | | | Mapping Rule - odd symbol | | | | | | | |
| 256-QAM | 8 | 0 | b8 | b9 | b10 | b11 | b12 | b13 | b14 | b15 |
| 256-QAM | 8 | 1 | b11 | b2 | b1 | b8 | b15 | b6 | b5 | b12 |

where N_{mod}, which is a modulation order, denotes a number of input bits mapped to one point in the constellation, and CRV denotes the constellation rearrangement version.

32. The apparatus of claim 30, wherein the first version of the constellation mapping rule is a mapping rule corresponding to a Constellation Rearrangement Version (CRV) 0 in the following table, and
the second version of the constellation mapping rule is a mapping rule corresponding to a CRV 1 in the following table:

| Constellation | N_{mod} | CRV | | | | | | | | |
|---|---|---|---|---|---|---|---|---|---|---|
| | | | Mapping Rule - even symbol | | | | | | | |
| 256-QAM | 8 | 0 | b0 | b1 | b2 | b3 | b4 | b5 | b6 | b7 |
| 256-QAM | 8 | 1 | b11 | b2 | b1 | b8 | b15 | b6 | b5 | b12 |
| | | | Mapping Rule - odd symbol | | | | | | | |
| 256-QAM | 8 | 0 | b8 | b9 | b10 | b11 | b12 | b13 | b14 | b15 |
| 256-QAM | 8 | 1 | b3 | b10 | b9 | b0 | b7 | b14 | b13 | b4 |

where N_{mod}, which is a modulation order, denotes a number of input bits mapped to one point in the constellation, and CRV denotes the constellation rearrangement version.

33. The apparatus of claim 30, wherein the first version of the constellation mapping rule is a mapping rule corresponding to a Constellation Rearrangement Version (CRV) 0 in the following table, and
the second version of the constellation mapping rule is a mapping rule corresponding to a CRV 1 in the following table:

| Constellation | N_{mod} | CRV | | | | | | | | |
|---|---|---|---|---|---|---|---|---|---|---|
| | | | Mapping Rule - even symbol | | | | | | | |
| 256-QAM | 8 | 0 | b0 | b1 | b2 | b3 | b4 | b5 | b6 | b7 |
| 256-QAM | 8 | 1 | b11 | b10 | b9 | b8 | b15 | b14 | b13 | b12 |
| | | | Mapping Rule - odd symbol | | | | | | | |
| 256-QAM | 8 | 0 | b8 | b9 | b10 | b11 | b12 | b13 | b14 | b15 |
| 256-QAM | 8 | 1 | b3 | b2 | b1 | b0 | b7 | b6 | b5 | b4 |

where N_{mod}, which is a modulation order, denotes a number of input bits mapped to one point in the constellation, and CRV denotes the constellation rearrangement version.

34. The apparatus of claim 30, wherein the first version of the constellation mapping rule is a mapping rule corresponding to a Constellation Rearrangement Version (CRV) 0 in the following table, and
the second version of the constellation mapping rule is a mapping rule corresponding to a CRV 1 in the following table:

| Constellation | N_{mod} | CRV | | | | | | | | |
|---|---|---|---|---|---|---|---|---|---|---|
| | | | Mapping Rule - even symbol | | | | | | | |
| 256-QAM | 8 | 0 | b0 | b1 | b2 | b3 | b4 | b5 | b6 | b7 |
| 256-QAM | 8 | 1 | b7 | b14 | b13 | b4 | b3 | b10 | b9 | b0 |
| | | | Mapping Rule - odd symbol | | | | | | | |
| 256-QAM | 8 | 0 | b8 | b9 | b10 | b11 | b12 | b13 | b14 | b15 |
| 256-QAM | 8 | 1 | b15 | b6 | b5 | b12 | b11 | b2 | b1 | b8 |

where N_{mod}, which is a modulation order, denotes a number of input bits mapped to one point in the constellation, and CRV denotes the constellation rearrangement version.

35. The apparatus of claim 30, wherein the first version of the constellation mapping rule is a mapping rule corresponding to a Constellation Rearrangement Version (CRV) 0 in the following table, and
the second version of the constellation mapping rule is a mapping rule corresponding to a CRV 1 in the following table:

| Constellation | N_{mod} | CRV | | | | | | | | |
|---|---|---|---|---|---|---|---|---|---|---|
| | | | Mapping Rule - even symbol | | | | | | | |
| 256-QAM | 8 | 0 | b0 | b1 | b2 | b3 | b4 | b5 | b6 | b7 |
| 256-QAM | 8 | 1 | b15 | b6 | b5 | b12 | b11 | b2 | b1 | b8 |
| | | | Mapping Rule - odd symbol | | | | | | | |
| 256-QAM | 8 | 0 | b8 | b9 | b10 | b11 | b12 | b13 | b14 | b15 |
| 256-QAM | 8 | 1 | b7 | b14 | b13 | b4 | b3 | b10 | b9 | b0 |

where N_{mod}, which is a modulation order, denotes a number of input bits mapped to one point in the constellation, and CRV denotes the constellation rearrangement version.

36. The apparatus of claim 30, wherein the first version of the constellation mapping rule is a mapping rule corresponding to a Constellation Rearrangement Version (CRV) 0 in the following table, and
the second version of the constellation mapping rule is a mapping rule corresponding to a CRV 1 in the following table:

| Constellation | N_{mod} | CRV | | | | | | | | |
|---|---|---|---|---|---|---|---|---|---|---|
| | | | Mapping Rule - even symbol | | | | | | | |
| 256-QAM | 8 | 0 | b0 | b1 | b2 | b3 | b4 | b5 | b6 | b7 |
| 256-QAM | 8 | 1 | b15 | b14 | b13 | b12 | b11 | b10 | b9 | b8 |
| | | | Mapping Rule - odd symbol | | | | | | | |
| 256-QAM | 8 | 0 | b8 | b9 | b10 | b11 | b12 | b13 | b14 | b15 |
| 256-QAM | 8 | 1 | b7 | b6 | b5 | b4 | b3 | b2 | b1 | b0 |

where N_{mod}, which is a modulation order, denotes a number of input bits mapped to one point in the constellation, and CRV denotes the constellation rearrangement version.

37. An apparatus of a receiver in a wireless access system, comprising:
a controller for verifying a constellation rearrangement version of a received packet; and
a constellation demapper for restoring a bitstream from complex symbols according to a first version of a constellation mapping rule when the version is the first version, and restoring a bitstream from complex symbols according to a second version of a constellation mapping rule when the version is the second version.

38. The apparatus of claim 37, wherein the constellation demapper demodulates the complex symbols according to 256-Quadrature Amplitude Modulation (QAM).

39. The apparatus of claim 38, wherein the first version of the constellation mapping rule and the second version of the constellation mapping rule comprises a relation of at least one of exchange of a first bit and a fourth bit, exchange of a second bit and a third bit, exchange of a fifth bit and an eighth bit, exchange of a sixth bit and a seventh bit, and exchange of an In-phase (I) channel and a Quadrature-phase (Q) channel.

40. The apparatus of claim 39, wherein the first version of the constellation mapping rule is a mapping rule corresponding to a Constellation Rearrangement Version (CRV) 0 in the following table, and
the second version of the constellation mapping rule is a mapping rule corresponding to a CRV 1 in the following table:

| Constellation | N_{mod} | CRV | Mapping Rule | | | | | | | |
|---|---|---|---|---|---|---|---|---|---|---|
| 256-QAM | 8 | 0 | b0 | b1 | b2 | b3 | b4 | b5 | b6 | b7 |
| 256-QAM | 8 | 1 | b7 | b6 | b5 | b4 | b3 | b2 | b1 | b0 |

where N_{mod}, which is a modulation order, denotes a number of input bits mapped to one point in a constellation, and CRV denotes the constellation rearrangement version.

41. The apparatus of claim 39, wherein the first version of the constellation mapping rule is a mapping rule corresponding to a Constellation Rearrangement Version (CRV) 0 in the following table, and
the second version of the constellation mapping rule is a mapping rule corresponding to a CRV 1 in the following table:

| Constellation | N_{mod} | CRV | Mapping Rule | | | | | | | |
|---|---|---|---|---|---|---|---|---|---|---|
| 256-QAM | 8 | 0 | b0 | b1 | b2 | b3 | b4 | b5 | b6 | b7 |
| 256-QAM | 8 | 1 | b3 | b2 | b1 | b0 | b7 | b6 | b5 | b4 |

where N_{mod}, which is a modulation order, denotes a number of input bits mapped to one point in the constellation, and CRV denotes the constellation rearrangement version.

42. The apparatus of claim 39, wherein at least one of the exchange of the first bit and the fourth bit, the exchange of the second bit and the third bit, the exchange of the fifth bit and the eighth bit, and the exchange of the sixth bit and the seventh bit is conducted between an even symbol and an odd symbol.

43. The apparatus of claim 42, wherein the first version of the constellation mapping rule is a mapping rule corresponding to a Constellation Rearrangement Version (CRV) 0 in the following table, and
the second version of the constellation mapping rule is a mapping rule corresponding to a CRV 1 in the following table:

| Constellation | N_{mod} | CRV | | | | | | | | |
|---|---|---|---|---|---|---|---|---|---|---|
| | | | Mapping Rule - even symbol | | | | | | | |
| 256-QAM | 8 | 0 | b0 | b1 | b2 | b3 | b4 | b5 | b6 | b7 |
| 256-QAM | 8 | 1 | b3 | b10 | b9 | b0 | b7 | b14 | b13 | b4 |
| | | | Mapping Rule - odd symbol | | | | | | | |
| 256-QAM | 8 | 0 | b8 | b9 | b10 | b11 | b12 | b13 | b14 | b15 |
| 256-QAM | 8 | 1 | b11 | b2 | b1 | b8 | b15 | b6 | b5 | b12 |

where N_{mod}, which is a modulation order, denotes a number of input bits mapped to one point in the constellation, and CRV denotes the constellation rearrangement version.

44. The apparatus of claim 42, wherein the first version of the constellation mapping rule is a mapping rule corresponding to a Constellation Rearrangement Version (CRV) 0 in the following table, and
the second version of the constellation mapping rule is a mapping rule corresponding to a CRV 1 in the following table:

| Constellation | N_{mod} | CRV | | | | | | | | |
|---|---|---|---|---|---|---|---|---|---|---|
| | | | Mapping Rule - even symbol | | | | | | | |
| 256-QAM | 8 | 0 | b0 | b1 | b2 | b3 | b4 | b5 | b6 | b7 |
| 256-QAM | 8 | 1 | b11 | b2 | b1 | b8 | b15 | b6 | b5 | b12 |
| | | | Mapping Rule - odd symbol | | | | | | | |
| 256-QAM | 8 | 0 | b8 | b9 | b10 | b11 | b12 | b13 | b14 | b15 |
| 256-QAM | 8 | 1 | b3 | b10 | b9 | b0 | b7 | b14 | b13 | b4 |

where N_{mod}, which is a modulation order, denotes a number of input bits mapped to one point in the constellation, and CRV denotes the constellation rearrangement version.

45. The apparatus of claim 42, wherein the first version of the constellation mapping rule is a mapping rule corresponding to a Constellation Rearrangement Version (CRV) 0 in the following table, and
the second version of the constellation mapping rule is a mapping rule corresponding to a CRV 1 in the following table:

| Constellation | N_{mod} | CRV | | | | | | | | |
|---|---|---|---|---|---|---|---|---|---|---|
| | | | Mapping Rule - even symbol | | | | | | | |
| 256-QAM | 8 | 0 | b0 | b1 | b2 | b3 | b4 | b5 | b6 | b7 |
| 256-QAM | 8 | 1 | b11 | b10 | b9 | b8 | b15 | b14 | b13 | b12 |
| | | | Mapping Rule - odd symbol | | | | | | | |
| 256-QAM | 8 | 0 | b8 | b9 | b10 | b11 | b12 | b13 | b14 | b15 |
| 256-QAM | 8 | 1 | b3 | b2 | b1 | b0 | b7 | b6 | b5 | b4 |

where N_{mod}, which is a modulation order, denotes a number of input bits mapped to one point in the constellation, and CRV denotes the constellation rearrangement version.

46. The apparatus of claim 42, wherein the first version of the constellation mapping rule is a mapping rule corresponding to a Constellation Rearrangement Version (CRV) 0 in the following table, and
the second version of the constellation mapping rule is a mapping rule corresponding to a CRV 1 in the following table:

| Constellation | N_{mod} | CRV | | | | | | | | |
|---|---|---|---|---|---|---|---|---|---|---|
| | | | Mapping Rule - even symbol | | | | | | | |
| 256-QAM | 8 | 0 | b0 | b1 | b2 | b3 | b4 | b5 | b6 | b7 |
| 256-QAM | 8 | 1 | b7 | b14 | b13 | b4 | b3 | b10 | b9 | b0 |
| | | | Mapping Rule - odd symbol | | | | | | | |
| 256-QAM | 8 | 0 | b8 | b9 | b10 | b11 | b12 | b13 | b14 | b15 |
| 256-QAM | 8 | 1 | b15 | b6 | b5 | b12 | b11 | b2 | b1 | b8 |

where N_{mod}, which is a modulation order, denotes a number of input bits mapped to one point in the constellation, and CRV denotes the constellation rearrangement version.

47. The apparatus of claim 42, wherein the first version of the constellation mapping rule is a mapping rule corresponding to a CRV 0 in the following table, and
the second version of the constellation mapping rule is a mapping rule corresponding to a CRV 1 in the following table:

| Constellation | N_{mod} | CRV | | | | | | | | |
|---|---|---|---|---|---|---|---|---|---|---|
| | | | Mapping Rule - even symbol | | | | | | | |
| 256-QAM | 8 | 0 | b0 | b1 | b2 | b3 | b4 | b5 | b6 | b7 |
| 256-QAM | 8 | 1 | b15 | b6 | b5 | b12 | b11 | b2 | b1 | b8 |
| | | | Mapping Rule - odd symbol | | | | | | | |
| 256-QAM | 8 | 0 | b8 | b9 | b10 | b11 | b12 | b13 | b14 | b15 |
| 256-QAM | 8 | 1 | b7 | b14 | b13 | b4 | b3 | b10 | b9 | b0 |

where N_{mod}, which is a modulation order, denotes a number of input bits mapped to one point in the constellation, and CRV denotes the constellation rearrangement version.

48. The apparatus of claim 42, wherein the first version of the constellation mapping rule is a mapping rule corresponding to a Constellation Rearrangement Version (CRV) 0 in the following table, and
the second version of the constellation mapping rule is a mapping rule corresponding to a CRV 1 in the following table:

| Constellation | N_{mod} | CRV | | | | | | | | |
|---|---|---|---|---|---|---|---|---|---|---|
| | | | Mapping Rule - even symbol | | | | | | | |
| 256-QAM | 8 | 0 | b0 | b1 | b2 | b3 | b4 | b5 | b6 | b7 |
| 256-QAM | 8 | 1 | b15 | b14 | b13 | b12 | b11 | b10 | b9 | b8 |
| | | | Mapping Rule - odd symbol | | | | | | | |
| 256-QAM | 8 | 0 | b8 | b9 | b10 | b11 | b12 | b13 | b14 | b15 |
| 256-QAM | 8 | 1 | b7 | b6 | b5 | b4 | b3 | b2 | b1 | b0 |

where N_{mod}, which is a modulation order, denotes a number of input bits mapped to one point in the constellation, and CRV denotes the constellation rearrangement version.
